(19) United States
(12) Patent Application Publication
(10) Pub. No.: US 2013/0311122 A1
(43) Pub. Date: Nov. 21, 2013

(54) TESTING SYSTEM

(71) Applicants: HONG FU JIN PRECISION INDUSTRY (ShenZhen) CO., LTD., (US); HON HAI PRECISION INDUSTRY CO., LTD., New Taipei (TW)

(72) Inventor: ZHI-GANG XU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/864,294

(22) Filed: Apr. 17, 2013

(30) Foreign Application Priority Data
May 18, 2012 (CN) 201210155177.X

(51) Int. Cl. G01R 13/02

(52) U.S. Cl. CPC G01R 13/0254
USPC 702/67

(57) ABSTRACT

A testing system includes a computer, a connection cord, and a number of oscillographs. The each oscillograph has a GPIB port. The computer has a USB port. The connection cord has a USB connector for connection with the USB port and a GPIB connector for selectively connecting to a GPIB port of one of the oscillographs. The computer includes an oscillograph model displaying module, an oscillograph driving module, a storage module, and a testing interface module. The oscillograph model displaying module displays a number of oscillograph models for a user to select. The oscillograph driving module loads an oscillograph driver corresponding to the selected oscillograph model. The storage module stores a plurality of codes associated with a number of testing functions for different oscillographs. The testing interface module transmits the codes to the oscillograph, thereby driving the oscillograph to perform the associated testing functions to test a device.

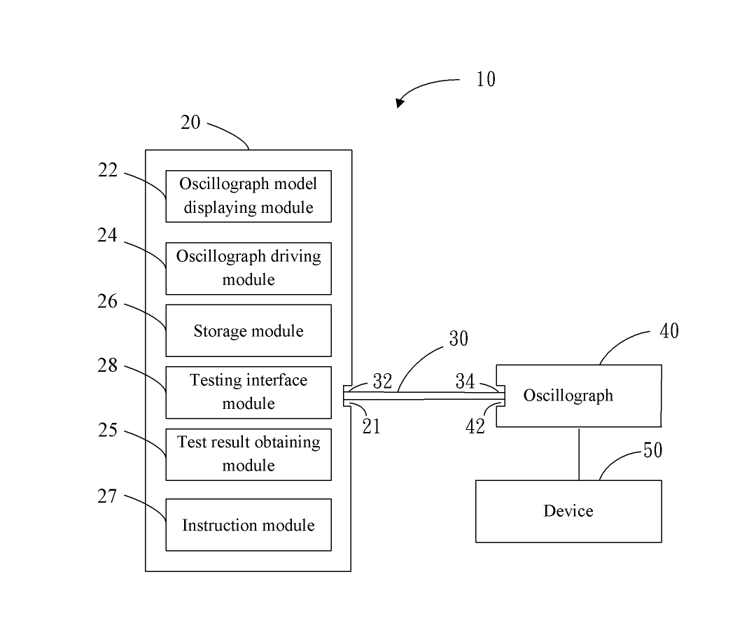

### BACKGROUND

1. Technical Field

The present disclosure relates to a testing system, especially to a testing system having an oscillograph.

2. Description of Related Art

Oscillographs are widely used in testing systems. Often many oscillographs of different types are needed, and each oscillograph is connected to a computer via a General Purpose Interface BUS. Thus, the computer needs to employ a special bus card to connect to the oscillograph, which increases costs of testing.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

The drawing is a block diagram of a testing system

### DETAILED DESCRIPTION

Referring to the drawing, a testing system 10 for testing a device 50 according to an exemplary embodiment includes a computer 20, a connection cord 30 and a number of different models of oscillographs 40. Each oscillograph 40 has a general purpose interface bus (GPIB) port 42. The connection cord 30 has a universal serial bus (USB) connector 32 at a first end, and a GPIB connector 34 at an opposing second end for selectively connecting to a GPIB port 42 of one of the oscillographs 40. The computer 20 has a USB port 21 for connection with the USB connector 32 of the connection cord 30. The computer 20 can be connected to the oscillographs 40 in turn by the connection cord 30.

The computer 20 includes an oscillograph model displaying module 22, an oscillograph driving module 24, a storage module 26, a testing interface module 28, and a test result obtaining module 25.

The oscillograph model displaying module 22 is configured for displaying a number of oscillograph models for a user to select according to the model of the oscillograph 40 which is connected to the computer 20 through the connection cord 30. The oscillograph driving module 24 is configured for loading an oscillograph driver corresponding to the selected oscillograph model.

The storage module 26 stores a number of codes for each of the different models of the oscillographs 40. The codes are associated with a plurality of testing functions. The testing interface module 28 is configured for transmitting the codes to oscillograph 40 connected to the computer 20, thereby driving the oscillograph 40 connected to the computer 20 to perform the associated testing functions to test the device 50. The test result obtaining module 25 is configured for obtaining the test result and outputting the test result to the user, such as on a display or printout.

In an alternative embodiment, the computer 20 further includes an instruction module 27. The instruction module 27 stores a number of instructions. The instructions are identifiable by the corresponding oscillograph 40. The testing interface module 28 is further configured for transmitting the instructions to the oscillograph 40 through the connection cord 30. The oscillograph 40 executes functions corresponding to the received instructions. For example, automatically enlarging the test result waveform displayed on the oscillograph 40, so that a user need not manipulate controls of the oscillograph 40.

The oscillographs 40 in the testing system 10 can be used to test the device 50 according to the codes stored in the storage module 26 of the computer 20. Only one connection cord 30 is needed to selectively connect the computer 20 to any of the number of oscillographs 40, which means a simple standard bus card may be used, all of which saves expense.

It is to be understood, however, that even though numerous characteristics and advantages of the present disclosure have been set forth in the foregoing description, together with details of the structure and function of the present disclosure, the present disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. A testing system configured for testing a device, comprising
a plurality of different models of oscillographs each having a general purpose interface bus (GPIB) port;
a connection cord having a universal serial bus (USB) connector at a first end, and a GPIB connector at an opposing second end for selectively connecting to a GPIB port of one of the oscillographs;
a computer comprising:
a USB port for connection with the USB connector of the connection cord,
an oscillograph model displaying module configured to display a plurality of oscillograph models for a user to select according to the model of the oscillograph which is connected to the computer through the connection cord;
an oscillograph driving module configured for loading an oscillograph driver corresponding to the selected oscillograph model;
a storage module configured for storing a plurality of codes for each of the different models of the oscillographs, the codes being associated with a plurality of testing functions;
a testing interface module configured for transmitting the codes to the oscillograph connected to the computer, thereby driving the oscillograph connected to the computer to perform the associated testing functions to test the device.

2. The testing system as described in claim 1, wherein the computer further comprises a test result obtaining module, the test result obtaining module is configured for obtaining and outputting the test result to the user.

3. The testing system as described in claim 1, wherein the computer further comprises an instruction module, the instruction module stores a plurality of instructions, the instruction are identifiable by the corresponding oscillograph, the testing interface module further is configured for transmitting the instructions to the oscillograph to execute the instructions.
